(19) United States
(12) Patent Application Publication
(10) Pub. No.: US 2024/0324400 A1
(43) Pub. Date: Sep. 26, 2024

(54) DISPLAY APPARATUS

(71) Applicant: Samsung Display Co., LTD., Yongin-si (KR)

(72) Inventors: Junghwa PARK, Yongin-si (KR); Bohwa KIM, Yongin-si (KR); Jincheol JANG, Yongin-si (KR); Jaehan LEE, Yongin-si (KR)

(21) Appl. No.: 18/414,037

(22) Filed: Jan. 16, 2024

(30) Foreign Application Priority Data
Mar. 24, 2023 (KR) 10-2023-0039205
Jun. 16, 2023 (KR) 10-2023-0077717

(51) Int. Cl. H10K 59/80; H10K 59/121; H10K 59/124; H10K 102/00

(52) U.S. Cl. CPC H10K 59/872; H10K 59/1213; H10K 59/124; H10K 59/873; H10K 2102/311

(57) ABSTRACT

A display apparatus with improved impact resistance includes a substrate, a first semiconductor layer disposed on the substrate, a first inorganic insulating layer disposed on the first semiconductor layer, a first gate layer disposed on the first inorganic insulating layer, having a compressive stress of 470 MPa or more and 1,540 MPa or less, and including molybdenum, and a second inorganic insulating layer disposed on the first gate layer.

### CROSS-REFERENCE TO RELATED APPLICATIONS

This application claims priority to Korean Patent Application No. 10-2023-0039205, filed on Mar. 24, 2023, and Korean Patent Application No. 10-2023-0077717, filed on Jun. 16, 2023, and all the benefits accruing therefrom under 35 U.S.C. § 119, the content of which in its entirety is herein incorporated by reference.

### BACKGROUND

### 1. Field

One or more embodiments relate to a display apparatus, and more particularly, to a display apparatus having improved impact resistance.

### 2. Description of the Related Art

Recently, display apparatuses have become more diversified in use. To implement various uses of a display apparatus, the display apparatus may be flexible so as to be bent or folded. Accordingly, research and development on flexible display devices have been conducted, and some flexible display apparatuses have been developed to be lightweight and thin. However, in a display apparatus in the related art, the strength of the display apparatus is reduced as the weight and thickness of the display apparatus decreases.

### SUMMARY

One or more embodiments include a display apparatus having improved impact resistance. However, these objectives are examples, and the scope of the disclosure is not limited thereto.

Additional aspects will be set forth in part in the description which follows and, in part, will be apparent from the description, or may be learned by practice of the presented embodiments of the disclosure.

According to one or more embodiments, a display apparatus includes a substrate, a first semiconductor layer disposed on the substrate, a first inorganic insulating layer disposed on the first semiconductor layer, a first gate layer disposed on the first inorganic insulating layer, having compressive stress of 470 megapascals (MPa) or more and 1,540 MPa or less, and including molybdenum, and a second inorganic insulating layer disposed on the first gate layer.

The first inorganic insulating layer may have compressive stress.

The first inorganic insulating layer may include at least one of silicon oxide, silicon nitride, and silicon oxynitride.

The second inorganic insulating layer may have compressive stress.

The second inorganic insulating layer may include at least one of silicon oxide, silicon nitride, and silicon oxynitride.

The display apparatus may further include a second semiconductor layer disposed over the second inorganic insulating layer, a third inorganic insulating layer disposed on the second semiconductor layer, a second gate layer disposed on the third inorganic insulating layer, and a fourth inorganic insulating layer disposed on the second gate layer.

The second gate layer may have compressive stress of 470 MPa or more and 1,540 MPa or less and include molybdenum.

The third inorganic insulating layer may have compressive stress, and the third inorganic insulating layer may include at least one of silicon oxide, silicon nitride, and silicon oxynitride.

The fourth inorganic insulating layer may have compressive stress, and the fourth inorganic insulating layer may include at least one of silicon oxide, silicon nitride, and silicon oxynitride.

The first semiconductor layer may include a silicon semiconductor, and the second semiconductor layer may have an oxide semiconductor.

According to one or more embodiments, a display apparatus includes a substrate, a pixel circuit layer disposed on the substrate, a display element layer disposed on the pixel circuit layer and including a display element, and an encapsulation layer disposed on the display element layer and including at least one inorganic encapsulation layer and at least one organic encapsulation layer, where the pixel circuit layer includes a first semiconductor layer disposed on the substrate, a first inorganic insulating layer disposed on the first semiconductor layer, a first gate layer disposed on the first inorganic insulating layer, having compressive stress of 470 MPa or more and 1,540 MPa or less, and including molybdenum, and a second inorganic insulating layer disposed on the first gate layer.

The first inorganic insulating layer may have compressive stress.

The first inorganic insulating layer may include at least one of silicon oxide, silicon nitride, and silicon oxynitride.

The second inorganic insulating layer may have compressive stress.

The second inorganic insulating layer may include at least one of silicon oxide, silicon nitride, and silicon oxynitride.

The pixel circuit layer may further include a second semiconductor layer disposed over the second inorganic insulating layer, a third inorganic insulating layer disposed on the second semiconductor layer, a second gate layer disposed on the third inorganic insulating layer, and a fourth inorganic insulating layer disposed on the second gate layer.

The second gate layer may have compressive stress of 470 MPa or more and 1,540 MPa or less and include molybdenum.

The third inorganic insulating layer may have compressive stress, and the third inorganic insulating layer may include at least one of silicon oxide, silicon nitride, and silicon oxynitride.

The fourth inorganic insulating layer may have compressive stress, and the fourth inorganic insulating layer may include at least one of silicon oxide, silicon nitride, and silicon oxynitride.

The first semiconductor layer may include a silicon semiconductor, and the second semiconductor layer may have an oxide semiconductor.

Other aspects, features, and advantages other than those described above will now become apparent from the following drawings, claims, and the detailed description of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1 and 2 are perspective views each schematically illustrating an embodiment of a display apparatus according to the present disclosure;

FIG. 3 is a schematic cross-sectional view of the display apparatus taken along a line A-A′ of FIG. 1;

FIG. 4 is a plan view schematically illustrating an embodiment of a display panel of a display apparatus according to the present disclosure;

FIG. 5 is an equivalent circuit diagram schematically illustrating an embodiment of a pixel circuit of a display panel and a display element connected to the pixel circuit;

FIG. 6 is a schematic cross-sectional view of the display panel taken along a line B-B′ of FIG. 4; and

FIG. 7 is a photomicrograph of a first gate electrode of an embodiment of a display apparatus according to the present disclosure.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. Effects and features of the disclosure and methods of achieving the same will be apparent with reference to embodiments and drawings described below in detail. The disclosure may, however, be embodied in many different forms and should not be construed as being limited to the embodiments set forth herein.

In the disclosure, while such terms as “first,” “second,” etc., may be used to describe various elements, such elements are not to be limited to the above terms.

In the disclosure, an expression used in the singular encompasses the expression of the plural, unless it has a clearly different meaning in the context.

In the disclosure, it is to be understood that the terms such as “including” and “having” are intended to indicate the existence of the features, or elements disclosed in the present disclosure, and are not intended to preclude the possibility that one or more other features or elements may exist or may be added.

In the present specification, “A and/or B” may include “A,” “B,” or “A and B.” In addition, “at least one of A and B” may include “A,” “B,” or “A and B.”

It will be understood that when a layer, region, or component is referred to as being “formed on” another layer, region, or component, it can be directly or indirectly formed on the other layer, region, or component, for example, intervening layers, regions, or components may be present.

In the disclosure, it will be understood that when a layer, region, or component is referred to as being connected to another layer, region, or component, it can be directly or indirectly connected to the other layer, region, or component. That is, for example, intervening layers, regions, or components may be present. For example, it will be understood that when a layer, region, or component is referred to as being electrically connected to another layer, region, or component, it can be directly or indirectly electrically connected to the other layer, region, or component. That is, for example, intervening layers, regions, or components may be present.

In the present disclosure, the x axis, the y axis, and the z axis are not limited to three rows on the orthogonal coordinates system, and may be interpreted in a broad sense including the same. For example, the x axis, the y axis, and the z axis may be perpendicular to one another, or may represent different directions that are not perpendicular to one another.

In the disclosure, “in a plan view” means that an object part is viewed from above. That is, in the disclosure, “in a plan view” may mean “when viewed from a direction perpendicular to a substrate 100”.

The disclosure will now be described more fully with reference to the accompanying drawings, in which embodiments of the disclosure are shown. Like reference numerals in the drawings denote like elements, and thus their description will be omitted. Sizes of components in the drawings may be exaggerated for convenience of explanation. In other words, since sizes and thicknesses of components in the drawings are arbitrarily illustrated for convenience of explanation, the following embodiments are not limited thereto.

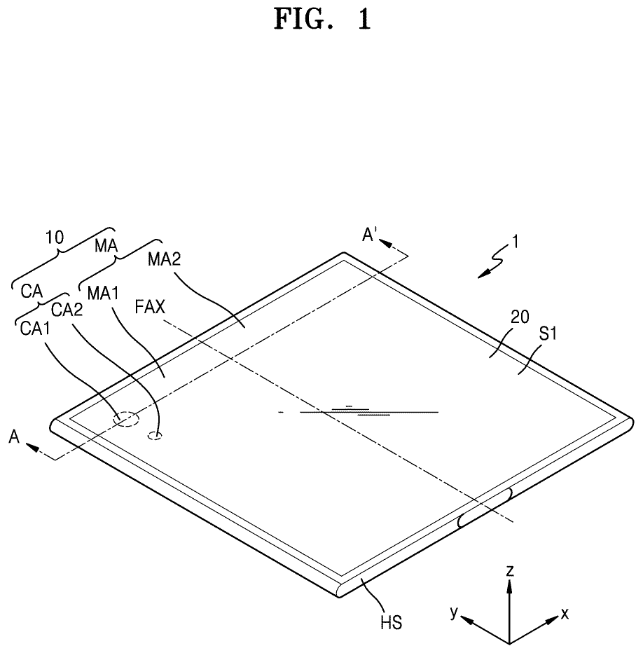

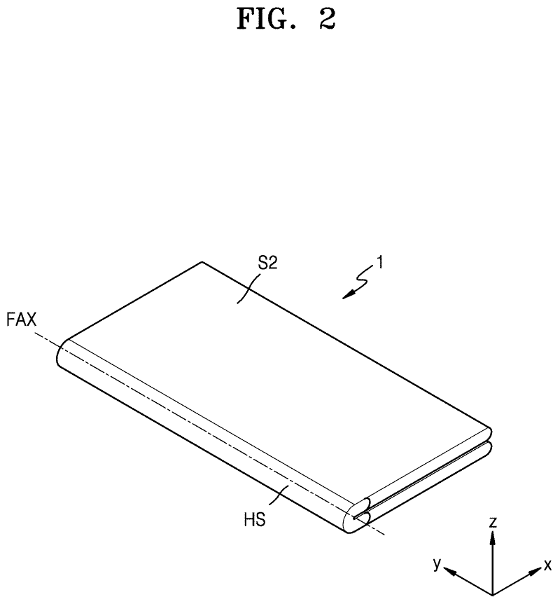

FIGS. 1 and 2 are perspective views each schematically illustrating an embodiment of a display apparatus 1 according to the present disclosure. In particular, FIG. 1 is a perspective view of the display apparatus 1 in an unfolded state, and FIG. 2 is a perspective view of the display apparatus 1 in a folded state.

As shown in FIGS. 1 and 2, the display apparatus 1 may include a housing HS, a display panel 10, and a cover window 20. The housing HS may include an inner surface defining an accommodation space. The housing HS may include a material having relatively high rigidity. For example, the housing HS may include a plurality of frames and/or plates including glass, plastic, metal, or a combination thereof. The housing HS may stably protect components of the display apparatus 1, which are accommodated in the inner space of the housing HS, from external impact.

The display panel 10 may display an image. The display panel 10 may include a main area MA and a component area CA. In an embodiment, the main area MA may be a main display area. A plurality of display elements may be arranged in the main area MA, and the plurality of display elements may emit light. Accordingly, the display panel 10 may display an image through light emitted by the plurality of display elements. In an embodiment, the display element may be an organic light-emitting diode including an organic emission layer. Alternatively, the display element may be a light-emitting diode (LED). The size of an LED may be in a micro scale or a nano scale. For example, the LED may be a micro-LED. Alternatively, the LED may be a nanorod LED. The nanorod LED may include gallium nitride (GaN). In an embodiment, a color converting layer may be disposed above the nanorod LED. The color converting layer may include quantum dots. Alternatively, the display element may be a quantum dot LED including a quantum dot emission layer. Alternatively, the display element may be an inorganic LED including an inorganic semiconductor.

The component area CA may be an area displaying an image and an area overlapping a component for adding various functions. A plurality of display elements may be arranged in the component area CA. The component area CA may be at least partially surrounded by the main area MA. In an embodiment, the component area CA may be entirely surrounded by the main area MA. In an embodiment, the component area CA may include a first component area CA1 and a second component area CA2. In an embodiment, any one of the first component area CA1 and the second component area CA2 may be omitted.

The cover window 20 may protect the display panel 10. In an embodiment, the cover window 20 may be coupled to the housing HS to provide the appearance of the display apparatus 1. The cover window 20 may include an insulating panel. For example, the cover window 20 may include glass, plastic, or a combination thereof. The cover window 20 may define a front surface of the display apparatus 1.

The cover window 20 may include an optically transparent area. Accordingly, the display panel 10 may display an image through a transparent area of the cover window 20, which is optically transparent. In an embodiment, the transparent area may be surrounded by a bezel area of the cover window 20, and the shape of the transparent area may be defined by the bezel area. The light transmittance of the bezel area may be lower than the light transmittance of the transparent area. In an embodiment, the bezel area may include an opaque material that blocks light. In an embodiment, the bezel area may have a certain color. The bezel area may be defined by a bezel layer provided separately from a transparent substrate defining the transparent area, or may be defined by an ink layer inserted into or colored in the transparent substrate.

As shown in FIGS. 1 and 2, the display apparatus 1 may include a first surface S1 and a second surface S2 opposite to the first surface S1. The display apparatus 1 may display an image on the first surface S1. In an embodiment, the first surface S1 may be a front surface of the display apparatus 1. The second surface S2 may be a rear surface of the display apparatus 1. In some embodiments, the display apparatus 1 may also display an image on the second surface S2.

The display apparatus 1 may be folded around a folding axis FAX crossing the first surface S1. In an embodiment, the display apparatus 1 may be folded such that a portion of the first surface S1 and another portion of the first surface S1 face each other. In another embodiment, the display apparatus 1 may be folded such that a portion of the second surface S2 and another portion of the second surface S2 face each other.

In an embodiment, the folding axis FAX may extend in a second direction intersecting a first direction. In another embodiment, the folding axis FAX may extend in the first direction. In an embodiment, the first direction and the second direction may form an acute angle. In an embodiment, the first direction and the second direction may form a right angle or an obtuse angle. Hereinafter, an example case where the first direction (e.g., x direction or −x direction) and the second direction (e.g., y direction or −y direction) are orthogonal to each other is mainly described in detail.

FIGS. 1 and 2 show one folding axis FAX, but in another embodiment, the display apparatus 1 may include a plurality of folding axes FAX. Also, FIGS. 1 and 2 show that the folding axis FAX extends in the second direction (e.g., y direction or −y direction), but in another embodiment, the folding axis FAX may extend in the first direction (e.g., x direction or −x direction) or a direction intersecting the first direction (e.g., x direction or −x direction) and the second direction (e.g., y direction or −y direction).

The display apparatus 1 may include the housing HS, the display panel 10, and the cover window 20. The display panel 10 may include the main area MA and the component area CA. In an embodiment, the main area MA may include a first main area MA1 and a second main area MA2 with the folding axis FAX therebetween. The component area CA may be at least partially surrounded by the main area MA. The component area CA may include the first component area CA1 and the second component area CA2. In the example of FIG. 1, the component area CA is surrounded by the first main area MA1, but in another embodiment, the component area CA may be surrounded by the second main area MA2.

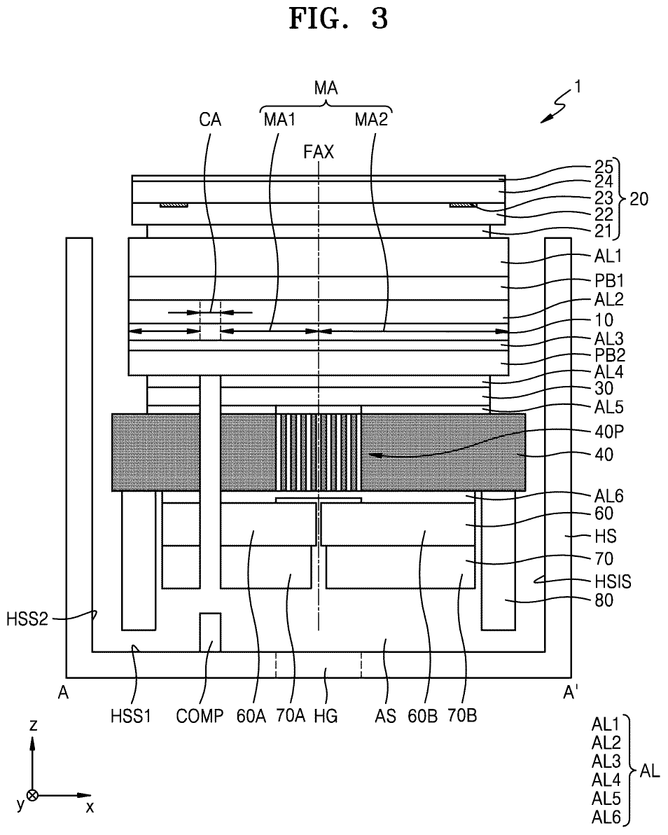

FIG. 3 is a schematic cross-sectional view of the display apparatus taken along a line A-A′ of FIG. 1.

Referring to FIG. 3, the display apparatus 1 may include the housing HS, the display panel 10, a cover window 20, a first protective layer PB1, a second protective layer PB2, a support layer 30, a first plate 40, a second plate 60, a cushion layer 70, a waterproof layer 80, an adhesive layer AL, and a component COMP.

The housing HS may include an inner side surface HSIS defining an accommodation space AS. The inner side surface HSIS of the housing HS may be a surface which does not configure the exterior of the display apparatus 1. In an embodiment, the housing HS may have a rear surface HSS1 and a side surface HSS2. The rear surface HSS1 and the side surface HSS2 may be surfaces which do not configure the exterior of the display apparatus 1. The display panel 10, the first protective layer PB1, the second protective layer PB2, the support layer 30, the first plate 40, the second plate 60, the cushion layer 70, the waterproof layer 80, the adhesive layer AL, and the component COMP may face the inner side surface HSIS of the housing HS.

Components of the display apparatus 1 may be arranged in the accommodation space AS. In an embodiment, the display panel 10, the first protective layer PB1, the second protective layer PB2, the support layer 30, the first plate 40, the second plate 60, the cushion layer 70, the waterproof layer 80, the adhesive layer AL, and the component COMP may be arranged in the accommodation space AS. In an embodiment, the housing HS may include a hinge area HG overlapping the folding axis FAX. Accordingly, the housing HS may be folded around the folding axis FAX.

The display panel 10 may be disposed under the cover window 20. In an embodiment, the display panel 10 may be arranged in the accommodation space AS. Accordingly, the housing HS may protect the display panel 10. The display panel 10 may include the main area MA and the component area CA. In an embodiment, the component area CA may overlap the component COMP. In an embodiment, the main area MA may include the first main area MA1 and the second main area MA2 with the folding axis FAX therebetween.

The cover window 20 may be disposed on the display panel 10. In an embodiment, the cover window 20 may be disposed over the housing HS. Although not illustrated in FIG. 3, the cover window 20 may be connected to the housing HS. The cover window 20 may include a window 21, a window adhesive layer 22, an opaque layer 23, a window protective layer 24, and a hard coating layer 25. In an embodiment, the window 21 may include ultra-thin glass. In another embodiment, the window 21 may include a polymer resin.

The window protective layer 24 may protect the window 21, and may prevent or reduce the occurrence of scratches on an upper surface of the window 21. The window protective layer 24 may be disposed above the window 21. In an embodiment, the window protective layer 24 may include a polymer resin. In another embodiment, the window protective layer 24 may include an inorganic material.

The window adhesive layer 22 may be disposed between the window protective layer 24 and the window 21. The window adhesive layer 22 may adhere the window protective layer 24 to the window 21. In an embodiment, the window adhesive layer 22 may be a pressure sensitive adhesive. In another embodiment, the window adhesive layer 22 may be an optically clear adhesive.

The opaque layer 23 may be disposed between the window adhesive layer 22 and the window protective layer 24. In some embodiments, the opaque layer 23 may be a portion of the window protective layer 24. The opaque layer 23 may include an opaque material such that wires or circuits of the display panel 10 are not identified from the outside. Accordingly, the opaque layer 23 may be a bezel area of the cover window 20.

The hard coating layer 25 may be disposed on the window protective layer 24. The hard coating layer 25 may be the outermost layer of the cover window 20. The hard coating layer 25 may be the outermost layer of the display apparatus 1. The hard coating layer 25 is a layer that a user directly touches, and the hard coating layer 25 may be smooth and soft to the touch. In an embodiment, the hard coating layer 25 may include a polymer resin. In another embodiment, the hard coating layer 25 may include an inorganic material.

The first protective layer PB1 may be disposed between the display panel 10 and the cover window 20. The first protective layer PB1 may protect the display panel 10 from external impact. In an embodiment, the first protective layer PB1 may include a polymer resin. For example, the first protective layer PB1 may include at least one of polyethersulfone, polyacrylate, polyetherimide, polyethylene naphthalate, polyethylene terephthalate, polyphenylene sulfide, polyimide, polycarbonate, and cellulose acetate propionate. In another embodiment, the first protective layer PB1 may include a material such as glass or quartz.

The second protective layer PB2 may be disposed under the display panel 10. In an embodiment, the display panel 10 may be disposed between the first protective layer PB1 and the second protective layer PB2. The second protective layer PB2 may protect the display panel 10 from external impact. In an embodiment, the second protective layer PB2 may include a polymer material. In another embodiment, the second protective layer PB2 may include an inorganic material.

The support layer 30 may be disposed under the second protective layer PB2. In an embodiment, the second protective layer PB2 may be disposed between the display panel 10 and the support layer 30. The support layer 30 may be disposed under the display panel 10 to support the display panel 10. The support layer 30 may include a polymer material.

The first plate 40 may be disposed under the support layer 30. In an embodiment, the support layer 30 may be disposed between the second protective layer PB2 and the first plate 40. The first plate 40 may be disposed under the support layer 30 to support the display panel 10. Accordingly, a degree that a center portion of the display panel 10 sags in a-z direction due to its weight (and/or due to an external impact applied to the display panel 10) is reduced, and thus the display panel 10 may not be easily damaged even when external impact is applied. Expressed another way, the first plate 40 may provide support to the display panel 10 in the z direction such that damage to the display panel 10 due to an external impact is prevented or reduced.

The first plate 40 may include a folding pattern 40P. The shape or length of the folding pattern 40P may change when the display apparatus 1 is folded. For example, the folding pattern 40P may be an opening portion provided in the first plate 40. In another embodiment, the folding pattern 40P a concave-and-convex shape. Expressed another way, some portions of the folding pattern 40P may be convex and protrude outward, and some portions of the folding pattern 40P may be concave and protrude inward. In another embodiment, the folding pattern 40P may include links rotatably connected to each other.

In an embodiment, when the display apparatus 1 is folded, the folding pattern 40P may be folded around the folding axis FAX. In an embodiment, the folding pattern 40P may be provided on both sides of the folding axis FAX such that the folding pattern 40P is symmetrical with respect to the folding axis FAX. In an embodiment, the first plate 40 may have a flat upper surface in an area not including the folding pattern 40P.

The first plate 40 may include at least one of metal, glass, and plastic. In an embodiment, the first plate 40 may include polyurethane. In another embodiment, the first plate 40 may include carbon fiber reinforced plastic (CFRP). In an embodiment, the folding pattern 40P may include the same material as the first plate 40 or a material different from that of the first plate 40.

The second plate 60 may be disposed under the first plate 40. That is, the first plate 40 may be disposed between the support layer 30 and the second plate 60. The second plate 60 may transfer heat generated by the display apparatus 1 to the outside. Also, the second plate 60 may protect the display apparatus 1 from external impact. In an embodiment, the second plate 60 may include a material with high heat transfer rate. For example, the second plate 60 may include metal or graphite. The second plate 60 may be relatively thin when the second plate 60 includes graphite as compared when the second plate 60 includes metal. In an embodiment, the second plate 60 may include a second-1 plate 60A and a second-2 plate 60B, which are spaced apart from each other with respect to the folding axis FAX. In an example, a gap between the second-1 plate 60A and the second-2 plate 60B may overlap the folding axis FAX.

Although not illustrated in FIG. 3, a digitizer (not shown) may be interposed between the first plate 40 and the second plate 60. The digitizer may include a body layer and/or a pattern layer. The digitizer may sense a signal input from an external electronic pen or the like through the pattern layer. In particular, the digitizer may sense the intensity, direction, or the like of a signal input by an electronic pen or the like. In this case, the digitizer may include a first digitizer and a second digitizer, which are spaced apart from each other with respect to the folding axis FAX. Accordingly, damage to the digitizer when the display apparatus 1 is folded may be prevented or reduced.

The cushion layer 70 may be disposed under the second plate 60. The second plate 60 may be disposed between the first plate 40 and the cushion layer 70. The cushion layer 70 may prevent or reduce damage to the display apparatus 1 from external impact. In particular, the thickness of components of the display apparatus 1 (in the z axis direction) may be such that the display apparatus 1 is able to be folded around the folding axis FAX (e.g., the components may be relatively thin). That is, the thickness of the display panel 10 (in the z axis direction) is such that the display panel 10 is thin. However, when the thickness of the display panel 10 (in the z axis direction) is such that the display panel 10 is thin, the display panel 10 may be susceptible to damage by external impact. The cushion layer 70 may prevent or reduce damage to the display panel 10 due to external impact by absorbing external impact applied to the display panel 10.

In an embodiment, the cushion layer 70 may include a material having viscoelasticity. In particular, the cushion layer 70 may include at least one of polyurethane, polyacrylate, and polyethylene. For example, the cushion layer 70 may include at least one of a urethane-based resin, an acrylate-based resin, and an ethylene-based resin. The cushion layer 70 may be a single-layer structure of a multi-layered structure, and may include a foam material similar to a sponge. In an embodiment, the cushion layer 70 may further include a pressure sensitive adhesive. In an embodiment, the cushion layer 70 may include a first portion 70A and a second portion 70B, which are spaced apart from each other with respect to the folding axis FAX (e.g., a gap between the first portion 70A and the second portion 70B may overlap the folding axis FAX).

The waterproof layer 80 may be arranged outside the second plate 60 and the cushion layer 70. The waterproof layer 80 may prevent or reduce damage to components of the display apparatus 1 due to moisture by blocking or absorbing moisture introduced from the outside of the display apparatus 1. In an embodiment, the waterproof layer 80 may include a tape and/or a sponge.

The adhesive layer AL may be disposed between a first component and a second component of the display apparatus 1. The adhesive layer AL may adhere the first component and the second component to each other. In an embodiment, the adhesive layer AL may be a pressure sensitive adhesive. In another embodiment, the adhesive layer AL may be an optically clear adhesive. The adhesive layer AL may include a first adhesive layer AL1, a second adhesive layer AL2, a third adhesive layer AL3, a fourth adhesive layer AL4, a fifth adhesive layer AL5, and a sixth adhesive layer AL6.

The first adhesive layer AL1 may be disposed between the first protective layer PB1 and the cover window 20. The first adhesive layer AL1 may adhere the first protective layer PB1 and the cover window 20 to each other. The second adhesive layer AL2 may be disposed between the first protective layer PB1 and the display panel 10. The second adhesive layer AL2 may adhere the first protective layer PB1 and the display panel 10 to each other. The third adhesive layer AL3 may be disposed between the display panel 10 and the second protective layer PB2. The third adhesive layer AL3 may adhere the display panel 10 and the second protective layer PB2 to each other. The fourth adhesive layer AL4 may be disposed between the second protective layer PB2 and the support layer 30.

The fourth adhesive layer AL4 may adhere the second protective layer PB2 and the support layer 30 to each other. The fifth adhesive layer AL5 may be disposed between the support layer 30 and the first plate 40. The fifth adhesive layer AL5 may adhere the support layer 30 and the first plate 40 to each other. In an embodiment, the fifth adhesive layer AL5 may not overlap the folding pattern 40P. The sixth adhesive layer AL6 may be disposed between the first plate 40 and the second plate 60. The sixth adhesive layer AL6 may adhere the first plate 40 and the second plate 60 to each other. In an embodiment, the sixth adhesive layer AL6 may prevent or reduce foreign materials from being introduced into the folding pattern 40P of the first plate 40.

The fourth adhesive layer AL4, the support layer 30, the fifth adhesive layer AL5, the first plate 40, the sixth adhesive layer AL6, the second plate 60, and the cushion layer 70 may each have a through hole overlapping the component area CA. In this case, sound transmittance and/or light transmittance from the outside to the component COMP may be increased. In another embodiment, at least one of the fourth adhesive layer AL4, the support layer 30, the fifth adhesive layer AL5, the first plate 40, the sixth adhesive layer AL6, the second plate 60, and the cushion layer 70 may not have a through hole overlapping the component area CA. In an embodiment, the second protective layer PB2 may be continuously arranged in the main area MA and the component area CA. In this case, the second protective layer PB2 may protect the display panel 10. In another embodiment, the second protective layer PB2 may have a through hole overlapping the component area CA.

The component COMP may be disposed between the housing HS and the display panel 10. In an embodiment, the component COMP may be attached to the housing HS. In another embodiment, the component COMP may be arranged in the accommodation space AS. The component COMP may be an electronic module. For example, the component COMP may be an electronic module that includes a sensor receiving and using light, such as an infrared sensor, a camera capturing an image by receiving light, a sensor outputting and sensing light or sound to measure a distance or recognize a fingerprint or the like, a small lamp outputting light, and/or a speaker outputting sound. In an example, the component COMP may be an electronic module using light having various wavelengths, such as, for example, visible light, infrared light, and/or ultraviolet light.

In an embodiment, the component COMP may include a light-emitting module and a light receiving module. The light-emitting module and the light receiving module may form an integral structure or a physically separated structure, and a pair of the light-emitting module and the light receiving module may form one component COMP.

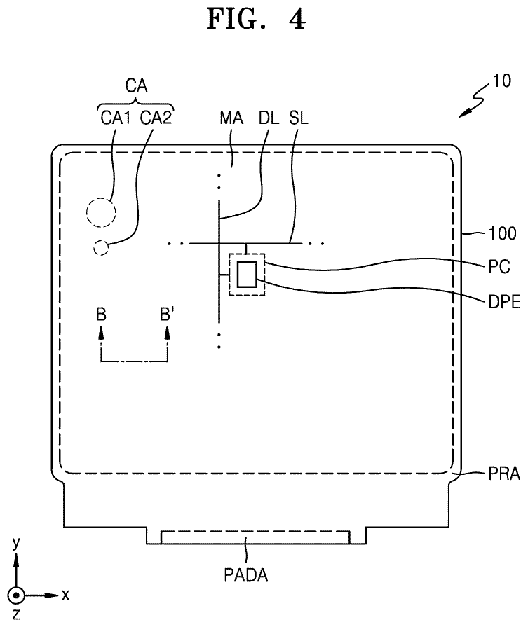

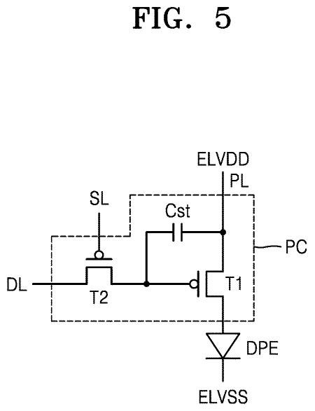

FIG. 4 is a plan view schematically illustrating an embodiment of the display panel 10 of a display apparatus according to the present disclosure. FIG. 5 is an equivalent circuit diagram schematically illustrating an embodiment of a pixel circuit PC of the display panel 10 and a display element DPE connected to the pixel circuit PC.

Referring to FIGS. 4 and 5, the display panel 10 may include the main area MA, the component area CA, and a peripheral area PRA. The display panel 10 may include a substrate 100, the pixel circuit PC, a scan line SL, a data line DL, a driving voltage line PL, and the display element DPE. In an embodiment, the main area MA, the component area CA, and the peripheral area PRA may be defined on the substrate 100. In other words, the substrate 100 may include the main area MA, the component area CA, and the peripheral area PRA. Hereinafter, an example case where the substrate 100 includes the main area MA, the component area CA, and the peripheral area PRA is mainly described in detail.

The pixel circuit PC and the display element DPE may overlap at least one of the main area MA and the component area CA. The pixel circuit PC may include a driving thin-film transistor T1, a switching thin-film transistor T2, and a storage capacitor Cst. The display element DPE may emit red, green, or blue light, or may emit red, green, blue, or white light.

The switching thin-film transistor T2 may be connected to the scan line SL and the data line DL, and be configured to transfer, to the driving thin-film transistor T1, a data voltage or a data signal input to the data line DL, according to a scan voltage or a scan signal input to the scan line SL.

The storage capacitor Cst may be connected to the switching thin-film transistor T2 and the driving voltage line PL, and store a voltage corresponding to a difference between a voltage received from the switching thin-film transistor T2 and a first power supply voltage ELVDD supplied to the driving voltage line PL.

The driving thin-film transistor T1 may be connected to the driving voltage line PL and the storage capacitor Cst, and may control a driving current flowing from the driving voltage line PL to the display element DPE in accordance with a voltage value stored in the storage capacitor Cst. The display element DPE may emit light having a certain brightness according to the driving current. An opposite electrode (e.g., a cathode) of the display element DPE may receive a second power supply voltage ELVSS.

Although in the example of FIG. 5, the pixel circuit PC includes two thin-film transistors and one storage capacitor, the pixel circuit PC may include three or more thin-film transistors.

The component area CA may be at least partially surrounded by the main area MA. In an embodiment, the component area CA may be entirely surrounded by the main area MA. The component area CA may include a pixel area in which the display element DPE is arranged and a transmission area in which the display element DPE is not arranged. Accordingly, the light transmittance of the display panel 10 in the component area CA may be higher than the light transmittance of the display panel 10 in the main area MA. In an embodiment, the component area CA may include the first component area CA1 and the second component area CA2.

The peripheral area PRA may be arranged outside the main area MA. In an embodiment, the peripheral area PRA may surround the main area MA. A scan driver (not shown) providing a scan signal to the pixel circuit PC, a data driver (not shown) providing a data signal, and a power supply line (not shown) providing the first power supply voltage ELVDD and/or the second power supply voltage ELVSS may be arranged in the peripheral area PRA. The peripheral area PRA may include a pad area PADA. A pad (not shown) may be arranged in the pad area PADA, and a display circuit board may be connected to the pad.

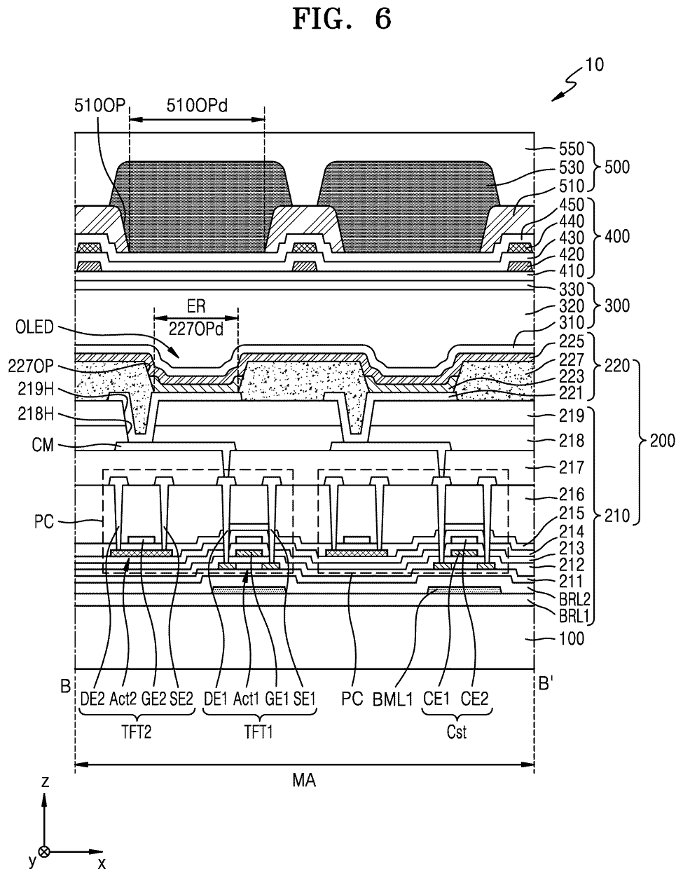

FIG. 6 is a schematic cross-sectional view of the display panel taken along a line B-B′ of FIG. 4. As shown in FIG. 6, the display panel 10 may include the substrate 100, a display layer 200, an encapsulation layer 300, a touch sensor layer 400, and an anti-reflection layer 500. The substrate 100 may include glass or a polymer resin, such as, for example, polyethersulfone, polyarylate, polyetherimide, polyethylene naphthalate, polyethylene terephthalate, polyphenylene sulfide, polyimide, polycarbonate, cellulose triacetate, cellulose acetate propionate, or the like. In an embodiment, the substrate 100 may have a multi-layered structure including a base layer and a barrier layer (not shown), wherein the base layer includes the polymer resin described herein. The substrate 100 including the polymer resin may be flexible, rollable, or bendable.

The display layer 200 may be disposed on the substrate 100. The display layer 200 may include a pixel circuit layer 210 and a display element layer 220.

The pixel circuit layer 210 may include a first barrier layer BRL1, a first metal layer BML1, a second barrier layer BRL2, the pixel circuit PC, a connection electrode CM, and a plurality of insulating layers. The pixel circuit PC may include a first thin-film transistor TFT1, a second thin-film transistor TFT2, and the storage capacitor Cst. The first thin-film transistor TFT1 may include a first semiconductor layer Act1, a first gate electrode GE1, a first source electrode SE1, and a first drain electrode DE1. The second thin-film transistor TFT2 may include a second semiconductor layer Act2, a second gate electrode GE2, a second source electrode SE2, and a second drain electrode DE2. The storage capacitor Cst may include a first electrode CE1 and a second electrode CE2. The plurality of insulating layers may include a buffer layer 211, a first inorganic insulating layer 212, a second inorganic insulating layer 213, an intermediate insulating layer 214, a third inorganic insulating layer 215, a fourth inorganic insulating layer 216, a first organic insulating layer 217, a second organic insulating layer 218, and a third organic insulating layer 219.

The first barrier layer BRL1 may be disposed on the substrate 100. The first barrier layer BRL1 may include an inorganic material, such as, for example, silicon oxide (SiO_{X}), silicon nitride (SiN_{X}), or silicon oxynitride (SiO_{X}N_{Y}).

In some embodiments, the first barrier layer BRL1 may include amorphous silicon (a-Si). In an embodiment, the first barrier layer BRL1 may include a single layer or multiple layers, each including the above material.

The first metal layer BML1 may be disposed on the first barrier layer BRL1. The first metal layer BML1 may overlap the first thin-film transistor TFT1. The first metal layer BML1 may serve as a lower protective metal protecting a layer overlapping the first metal layer BML1. In an embodiment, the first metal layer BML1 may not overlap the second thin-film transistor TFT2. In some embodiments, the first metal layer BML1 may be applied with an electrostatic voltage or a signal. The first metal layer BML1 may more easily provide charges to a back channel of the pixel circuit PC. Expressed another way, properties of the first metal layer BML1 may support providing charges to the back channel of the pixel circuit PC, for example, for cases in which an electrostatic voltage or a signal is applied to the first metal layer BML1. The first metal layer BML1 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu). In an embodiment, the first metal layer BML1 may include doped amorphous silicon. The first metal layer BML1 may include a single layer or multiple layers, each including the above materials.

The second barrier layer BRL2 may be disposed on the first barrier layer BRL1. The second barrier layer BRL2 may include an inorganic material, such as, for example, silicon oxide (SiO_{X}), silicon nitride (SiN_{X}), or silicon oxynitride (SiO_{X}N_{Y}). In some embodiments, the second barrier layer BRL2 may include amorphous silicon (a-Si). In an embodiment, the second barrier layer BRL2 may include a single layer or multiple layers, each including the above materials.

The buffer layer 211 may be disposed on the second barrier layer BRL2. The buffer layer 211 may include an inorganic material, such as, for example, silicon oxide (SiO_{X}), silicon nitride (SiN_{X}), or silicon oxynitride (SiO_{X}N_{Y}), and may include a single layer or multiple layers, each including the above inorganic material.

The first semiconductor layer Act1 may be disposed on the buffer layer 211. The first semiconductor layer Act1 may include a silicon semiconductor. In an embodiment, the first semiconductor layer Act1 may include polysilicon. The first semiconductor layer Act1 may include a channel area, a drain area, and a source area, wherein the drain area and the source area are respectively arranged on both sides of the channel area. In another embodiment, the first semiconductor layer Act1 may include an organic semiconductor or an oxide semiconductor.

The first inorganic insulating layer 212 may be disposed on the first semiconductor layer Act1. The first inorganic insulating layer 212 may include an inorganic insulating material, such as, for example, silicon oxide (SiO_{X}), silicon nitride (SiN_{X}), or silicon oxynitride (SiO_{X}N_{Y}). That is, the first inorganic insulating layer 212 may include at least one of silicon oxide (SiO_{X}), silicon nitride (SiN_{X}), and silicon oxynitride (SiO_{X}N_{Y}). In an embodiment, the first inorganic insulating layer 212 may include aluminum oxide (Al₂O₃), titanium oxide (TiO₂), tantalum oxide (Ta₂O₅), hafnium oxide (HfO₂), or zinc oxide (ZnO). The first gate electrode GE1 may be disposed on the first inorganic insulating layer 212. The first gate electrode GE1 may overlap the first semiconductor layer Act1. The first gate electrode GE1 may include Mo. The first gate electrode GE1 may include multiple layers or a single layer, each including Mo. The first gate electrode GE1 is described in more detail below.

The second inorganic insulating layer 213 may be disposed on the first gate electrode GE1. The second inorganic insulating layer 213 may include an inorganic insulating material, such as, for example, silicon oxide (SiO_{X}), silicon nitride (SiN_{X}), or silicon oxynitride (SiO_{X}N_{Y}). That is, the second inorganic insulating layer 213 may include at least one of silicon oxide (SiO_{X}), silicon nitride (SiN_{X}), and silicon oxynitride (SiO_{X}N_{Y}). In an embodiment, the second inorganic insulating layer 213 may include aluminum oxide (Al₂O₃), titanium oxide (TiO₂), tantalum oxide (Ta₂O₅), hafnium oxide (HfO₂), or zinc oxide (ZnO).

The second electrode CE2 may be disposed on the second inorganic insulating layer 213. In an embodiment, the second electrode CE2 may overlap the first gate electrode GE1 (also labeled as first electrode CE1 at the right of FIG. 6). The second electrode CE2 and the first gate electrode GE1, which overlap each other with the second inorganic insulating layer 213 there between, may form the storage capacitor Cst. That is, the first gate electrode GE1 may function as the first electrode CE1 of the storage capacitor Cst. As such, the storage capacitor Cst may overlap the first thin-film transistor TFT1. In another embodiment, the storage capacitor Cst may be disposed such that the storage capacitor Cst does not overlap the first thin-film transistor TFT1. The second electrode CE2 may include Al, Pt, Pd, Ag, Mg, Au, Ni, Nd, Ir, Cr, Ca, Mo, Ti, W, and/or Cu, and may include a single layer or multiple layers, each including the above material.

The intermediate insulating layer 214 may be disposed on the second electrode CE2. The intermediate insulating layer 214 may include an inorganic insulating material, such as, for example, silicon oxide (SiO_{X}), silicon nitride (SiN_{X}), or silicon oxynitride (SiO_{X}N_{Y}). That is, the intermediate insulating layer 214 may include at least one of silicon oxide (SiO_{X}), silicon nitride (SiN_{X}), and silicon oxynitride (SiO_{X}N_{Y}). In an embodiment, the intermediate insulating layer 214 may include aluminum oxide (Al₂O₃), titanium oxide (TiO₂), tantalum oxide (Ta₂O₅), hafnium oxide (HfO₂), or zinc oxide (ZnO).

The second semiconductor layer Act2 may be disposed on the intermediate insulating layer 214. That is, the second semiconductor layer Act2 may be disposed over the second inorganic insulating layer 213. The second semiconductor layer Act2 may include a channel area, a source area, and a drain area, wherein the source area and the drain area are respectively arranged on both sides of the channel area. The second semiconductor layer Act2 may include an oxide semiconductor. For example, the second semiconductor layer Act2 may include a zinc-oxide-based material, and may include Zn oxide, In—Zn oxide, Ga—In—Zn oxide, or the like. Alternatively, the second semiconductor layer Act2 may include an In—Ga—Zn—O (IGZO), In—Sn—Zn—O (ITZO), or In—Ga—Sn—Zn—O (IGTZO) semiconductor, which includes a metal such as In, Ga, and tin (Sn) in ZnO.

The source area and the drain area of the second semiconductor layer Act2 may be formed by adjusting a carrier concentration of an oxide semiconductor such that the source area and the drain area are conductive. For example, the source area and the drain area of the second semiconductor layer Act2 may be formed by increasing the carrier concentration through a plasma treatment using a hydrogen-based gas, a fluorine-based gas, or a combination thereof on the oxide semiconductor.

The third inorganic insulating layer 215 may be disposed on the second semiconductor layer Act2. The third inorganic insulating layer 215 may include an inorganic insulating material, such as, for example, silicon oxide (SiO_{X}), silicon nitride (SiN_{X}), or silicon oxynitride (SiO_{X}N_{Y}). That is, the third inorganic insulating layer 215 may include at least one of silicon oxide (SiO_{X}), silicon nitride (SiN_{X}), and silicon oxynitride (SiO_{X}N_{Y}). In an embodiment, the third inorganic insulating layer 215 may include aluminum oxide (Al₂O₃), titanium oxide (TiO₂), tantalum oxide (Ta₂O₅), hafnium oxide (HfO₂), or zinc oxide (ZnO).

The second gate electrode GE2 may be disposed on the third inorganic insulating layer 215. The second gate electrode GE2 may overlap the second semiconductor layer Act2. The second gate electrode GE2 may overlap the channel area of the second semiconductor layer Act2. The second gate electrode GE2 may include Mo. The second gate electrode GE2 may include multiple layers or a single layer, each including Mo. The second gate electrode GE2 is described in more detail below.

The fourth inorganic insulating layer 216 may be disposed on the second gate electrode GE2. The fourth inorganic insulating layer 216 may include an inorganic insulating material, such as, for example, silicon oxide (SiO_{X}), silicon nitride (SiN_{X}), or silicon oxynitride (SiO_{X}N_{Y}). That is, the fourth inorganic insulating layer 216 may include at least one of silicon oxide (SiO_{X}), silicon nitride (SiN_{X}), and silicon oxynitride (SiO_{X}N_{Y}). In an embodiment, the fourth inorganic insulating layer 216 may include aluminum oxide (Al₂O₃), titanium oxide (TiO₂), tantalum oxide (Ta₂O₅), hafnium oxide (HfO₂), or zinc oxide (ZnO). The fourth inorganic insulating layer 216 may include a single layer or multiple layers, each including the above inorganic insulating material.

The first source electrode SE1 and the first drain electrode DE1 may be disposed on the fourth inorganic insulating layer 216. The first source electrode SE1 and the first drain electrode DE1 may each be connected to the first semiconductor layer Act1. In an embodiment, the first source electrode SE1 and the first drain electrode DE1 may be connected to the first semiconductor layer Act1 through contact holes of respective insulating layers. For example, the first source electrode SE1 and the first drain electrode DE1 may be connected to the first semiconductor layer Act1 through each of a contact hole of the first inorganic insulating layer 212, a contact hole of the second inorganic insulating layer 213, a contact hole of the intermediate insulating layer 214, a contact hole of the third inorganic insulating layer 215, and a contact hole of the fourth inorganic insulating layer 216. The contact hole of the first inorganic insulating layer 212, the contact hole of the second inorganic insulating layer 213, the contact hole of the intermediate insulating layer 214, the contact hole of the third inorganic insulating layer 215, and the contact hole of the fourth inorganic insulating layer 216 may overlap each other.

The second source electrode SE2 and the second drain electrode DE2 may be disposed on the fourth inorganic insulating layer 216. The second source electrode SE2 and the second drain electrode DE2 may each be connected to the second semiconductor layer Act2. The second source electrode SE2 and the second drain electrode DE2 may be connected to the second semiconductor layer Act2 through each of a contact hole of the third inorganic insulating layer 215 and a contact hole of the fourth inorganic insulating layer 216.

The first source electrode SE1, the first drain electrode DE1, the second source electrode SE2, and the second drain electrode DE2 may each include a material with relatively high conductivity. The first source electrode SE1, the first drain electrode DE1, the second source electrode SE2, and the second drain electrode DE2 may each include a conductive material including Mo, Al, Cu, Ti, or the like, and may include multiple layers or a single layer, each including the above material. In an embodiment, the first source electrode SE1, the first drain electrode DE1, the second source electrode SE2, and the second drain electrode DE2 may each have a multi-layered structure of Ti/Al/Ti.

The first thin-film transistor TFT1 including the first semiconductor layer Act1 including a silicon semiconductor has high reliability, and the first thin-film transistor TFT1 may be used as a driving thin-film transistor to form the display panel 10 with high quality.

Because an oxide semiconductor has high carrier mobility and low leakage current, a voltage drop associated with a thin-film transistor including the oxide semiconductor may not be large (e.g., may be below a voltage threshold) even when a driving time associated with driving the thin-film transistor is long (e.g., above a threshold temporal duration). That is, because color change of an image according to the voltage drop is not large even during low-frequency driving, low-frequency driving is possible. In this way, because an oxide semiconductor has an advantage of having a small leakage current, leakage current of the pixel circuit PC may be prevented and power consumption may be reduced at the same time by using an oxide semiconductor in at least one of thin-film transistors (e.g., second thin-film transistor TFT2) other than the driving thin-film transistor (e.g., first thin-film transistor TFT1). For example, the second thin-film transistor TFT2 may include the second semiconductor layer Act2 including an oxide semiconductor.

The first organic insulating layer 217 may be arranged to cover the first source electrode SE1, the first drain electrode DE1, the second source electrode SE2, and the second drain electrode DE2. The first organic insulating layer 217 may include an organic material. For example, the first organic insulating layer 217 may include a general commercial polymer such as, for example, polymethyl methacrylate (PMMA) or polystyrene (PS), a polymer derivative having a phenol group, and an organic insulating material such as an acrylic polymer, an imide polymer, an aryl ether polymer, an amide polymer, a fluorine polymer, a p-xylene polymer, a vinyl alcohol polymer, and a mixture thereof.

The connection electrode CM may be disposed on the first organic insulating layer 217. The connection electrode CM may be connected to the first drain electrode DE1 or the first source electrode SE1 through a contact hole of the first organic insulating layer 217. The connection electrode CM may include a material having relatively high conductivity. The connection electrode CM may include a conductive material including Mo, Al, Cu, Ti, or the like, and may include multiple layers or a single layer, each including the above material. In an embodiment, the connection electrode CM may have a multi-layered structure of Ti/Al/Ti.

The second organic insulating layer 218 and the third organic insulating layer 219 may be disposed on the connection electrode CM. The second organic insulating layer 218 and the third organic insulating layer 219 may each include an organic material. For example, at least one of the second organic insulating layer 218 and the third organic insulating layer 219 may include a general commercial polymer such as, for example, PMMA or PS, a polymer derivative having a phenol group, and an organic insulating material, such as, for example, an acrylic polymer, an imide polymer, an aryl ether polymer, an amide polymer, a fluorine polymer, a p-xylene polymer, a vinyl alcohol polymer, and a mixture thereof. Because the second organic insulating layer 218 and the third organic insulating layer 219 are sequentially stacked, the display element layer 220 may be disposed on the pixel circuit layer 210 with a flat surface. In some embodiments, the third organic insulating layer 219 may be omitted.

The display element layer 220 may be disposed on the pixel circuit layer 210. The display element layer 220 may include a display element, for example, an organic light-emitting diode OLED. A plurality of organic light-emitting diodes OLED may be provided in the main area MA. That is, the plurality of organic light-emitting diodes OLED may be arranged in the main area MA. The organic light-emitting diode OLED may include a pixel electrode 221, an emission layer 223, an opposite electrode 225, and a pixel defining layer 227.

The pixel electrode 221 may be disposed on the third organic insulating layer 219. The pixel electrode 221 may be connected to the connection electrode CM through a contact hole 218H of the second organic insulating layer 218 and a contact hole 219H of the third organic insulating layer 219. The pixel electrode 221 may include a conductive oxide, such as, for example, indium tin oxide (ITO), indium zinc oxide (IZO), zinc oxide (ZnO), indium oxide (In₂O₃), indium gallium oxide (IGO), or aluminum zinc oxide (AZO). In another embodiment, the pixel electrode 221 may include a reflective film including Ag, Mg, Al, Pt, Pd, Au, Ni, Nd, Ir, Cr, or a compound thereof. In another embodiment, the pixel electrode 221 may further include a film including ITO, IZO, ZnO, or In₂O₃ above/below the reflective film mentioned above.

The pixel defining layer 227 may include an opening portion 227OP exposing at least a portion of the pixel electrode 221. The opening portion 227OP of the pixel defining layer 227 may define an emission area ER of the organic light-emitting diode OLED. The emission area ER of the organic light-emitting diode OLED may be referred to as a sub-pixel. In an embodiment, the pixel defining layer 227 may include a plurality of opening portions 227OP. The plurality of opening portions 227OP may define a plurality of emission areas ER of a plurality of organic light-emitting diodes OLED.

The pixel defining layer 227 may include an organic insulating material. In another embodiment, the pixel defining layer 227 may include an inorganic insulating material, such as, for example, silicon oxide (SiO_{X}), silicon nitride (SiN_{X}), or silicon oxynitride (SiON). In another embodiment, the pixel defining layer 227 may include an organic insulating material and an inorganic insulating material. In some embodiments, the pixel defining layer 227 may include a light-blocking material, and may be provided in black. The light-blocking material may include carbon black, carbon nanotubes, a resin or paste including a black dye, metal particles, such as, for example, nickel, aluminum, molybdenum, and alloys thereof, metal oxide particles (e.g., chromium oxide), metal nitride particles (e.g., chromium nitride), or the like. When the pixel defining layer 227 includes the light-blocking material, reflection of external light by metal structures disposed under the pixel defining layer 227 may be reduced.

The emission layer 223 may be arranged in the opening portion 227OP of the pixel defining layer 227. The emission layer 223 may include a polymer organic material or a low-molecular-weight organic material, which emits light of a certain color. Although not illustrated in FIG. 6, a first functional layer and a second functional layer may be respectively disposed below and above the emission layer 223. The first functional layer may include, for example, a hole transport layer (HTL) or may include an HTL and a hole injection layer (HIL). The second functional layer, as a component disposed on the emission layer 223, may be included or omitted. The second functional layer may include an electron transport layer (ETL) and/or an electron injection layer (EIL). Similar to the opposite electrode 225 to be described below, the first functional layer and/or the second functional layer may be a common layer entirely covering the substrate 100.

The opposite electrode 225 may be disposed on the emission layer 223. The opposite electrode 225 may include a conductive material having a low work function. For example, the opposite electrode 225 may include a (semi)transparent layer, the (semi)transparent layer including Ag, Mg, Al, Pt, Pd, Au, Ni, Nd, Ir, Cr, lithium (Li), Ca, alloys thereof, or the like. Alternatively, the opposite electrode 225 may further include a layer, such as, for example, ITO, IZO, ZnO, or In₂O₃, above the (semi)transparent layer including the above-stated material. In some embodiments, a capping layer (not shown) may be further disposed on the opposite electrode 225. The capping layer may include lithium fluoride (LiF), an inorganic material, or/and an organic material.

The encapsulation layer 300 may be disposed on the display element layer 220. The encapsulation layer 300 may protect the display element layer 220. In an embodiment, the encapsulation layer 300 may include at least one inorganic encapsulation layer and at least one organic encapsulation layer. The at least one inorganic encapsulation layer may include at least one inorganic encapsulation layer from among aluminum oxide (Al₂O₃), titanium oxide (TiO₂), tantalum oxide (Ta₂O₅), zinc oxide (ZnO), silicon oxide (SiO_{X}), silicon nitride (SiN_{X}), and silicon oxynitride (SiO_{X}N_{Y}). The at least one organic encapsulation layer may include a polymer-based material. The polymer-based material may include an acrylic resin, an epoxy resin, polyimide, polyethylene, or the like. In an embodiment, the at least one organic encapsulation layer may include acrylate. In an embodiment, the encapsulation layer 300 may include a first inorganic encapsulation layer 310, an organic encapsulation layer 320, and a second inorganic encapsulation layer 330, which are sequentially stacked.

The touch sensor layer 400 may be disposed on the encapsulation layer 300. The touch sensor layer 400 may include a first touch insulating layer 410, a first touch conductive pattern 420, a second touch insulating layer 430, a second touch conductive pattern 440, and a third touch insulating layer 450.

The first touch insulating layer 410 may be disposed on the second inorganic encapsulation layer 330. In an embodiment, the first touch insulating layer 410 may include a single layer or multiple layers, each including an inorganic material such as, for example, silicon oxide (SiO_{X}), silicon nitride (SiN_{X}), or silicon oxynitride (SiO_{X}N_{Y}). In some embodiments, the first touch insulating layer 410 may include an organic material. In some embodiments, the first touch insulating layer 410 may be omitted.

The first touch conductive pattern 420 may be disposed on the first touch insulating layer 410 and/or the second inorganic encapsulation layer 330. In an embodiment, the first touch conductive pattern 420 may overlap the pixel defining layer 227. The first touch conductive pattern 420 may not overlap the opening portion 227OP of the pixel defining layer 227. The first touch conductive pattern 420 may include a conductive material. For example, the first touch conductive pattern 420 may include Mo, Al, Cu, Ti, or the like, and may include multiple layers or a single layer, each including the above material. In an embodiment, the first touch conductive pattern 420 may have a structure in which a titanium layer, an aluminum layer, and a titanium layer are sequentially stacked (Ti/Al/Ti).

The second touch insulating layer 430 may cover the first touch conductive pattern 420. The second touch insulating layer 430 may include a single layer or a multi-layer, each including an inorganic material such as, for example, silicon oxide (SiO_{X}), silicon nitride (SiN_{X}), or silicon oxynitride (SiO_{X}N_{Y}). In some embodiments, the second touch insulating layer 430 may include an organic material.

The second touch conductive pattern 440 may be disposed on the second touch insulating layer 430. In an embodiment, the second touch conductive pattern 440 may overlap the pixel defining layer 227. The second touch conductive pattern 440 may not overlap the opening portion 227OP of the pixel defining layer 227. In an embodiment, the second touch conductive pattern 440 may be connected to the first touch conductive pattern 420 through a contact hole provided in the second touch insulating layer 430. The second touch conductive pattern 440 may include a conductive material. For example, the second touch conductive pattern 440 may include Mo, Al, Cu, Ti, or the like, and may include multiple layers or a single layer, each including the above material. In an embodiment, the second touch conductive pattern 440 may have a structure in which a titanium layer, an aluminum layer, and a titanium layer are sequentially stacked (Ti/Al/Ti).

The first touch conductive pattern 420 and the second touch conductive pattern 440 may each include a plurality of sensing electrodes (not shown) for sensing touch inputs. In an embodiment, the plurality of sensing electrodes may sense an input in a mutual capacitance manner. In another embodiment, the plurality of sensing electrodes may sense an input in a self-capacitance manner.

The third touch insulating layer 450 may cover the second touch conductive pattern 440. In an embodiment, the third touch insulating layer 450 may include a single layer or multiple layers, each including an inorganic material such as, for example, silicon oxide (SiO_{X}), silicon nitride (SiN_{X}), or silicon oxynitride (SiO_{X}N_{Y}). In some embodiments, the third touch insulating layer 450 may include an organic material.

The anti-reflection layer 500 may be disposed on the touch sensor layer 400. The anti-reflection layer 500 may include a black matrix 510, a color filter 530, and a planarization layer 550.

The black matrix 510 may be disposed on the third touch insulating layer 450. The black matrix 510 may at least partially absorb external light or internally-reflected light. The black matrix 510 may include a black pigment. The black matrix 510 may overlap the first touch conductive pattern 420 and/or the second touch conductive pattern 440. Accordingly, the black matrix 510 may prevent or reduce reflection of light by the first touch conductive pattern 420 and/or the second touch conductive pattern 440.

The black matrix 510 may include an upper opening portion 510OP overlapping the opening portion 227OP of the pixel defining layer 227. A plurality of upper opening portions 510OP may be provided in the main area MA. The plurality of upper opening portions 510OP may respectively overlap the plurality of opening portions 227OP in the main area MA.

A size of the upper opening portion 510OP may be larger than a size of the opening portion 227OP of the pixel defining layer 227. The size of the upper opening portion 510OP may be an area of the upper opening portion 510OP in a plan view. The size of the opening portion 227OP of the pixel defining layer 227 may be an area of the opening portion 227OP of the pixel defining layer 227 in a plan view. In an embodiment, a width 5200Pd of the upper opening portion 510OP may be larger than a width 2270Pd of the opening portion 227OP of the pixel defining layer 227. The width 5200Pd of the upper opening portion 510OP may be the shortest distance between a portion of the black matrix 510 and another portion of the black matrix 510, which face each other and define the upper opening portion 510OP. The width 2270Pd of the opening portion 227OP of the pixel defining layer 227 may be the shortest distance between a portion of the pixel defining layer 227 and another portion of the pixel defining layer 227, which face each other and define the opening portion 227OP. Accordingly, light emitted by the organic light-emitting diode OLED may travel at a wide angle.

The color filter 530 may prevent or reduce reflection of light from the display panel 10. The color filter 530 may overlap the organic light-emitting diode OLED. In an embodiment, the color filter 530 may overlap the upper opening portion 510OP. In an embodiment, a plurality of color filters 530 may be provided. The plurality of color filters 530 may overlap the main area MA. The plurality of color filters 530 may respectively overlap a plurality of upper opening portions 510OP in the main area MA. In an embodiment, among the plurality of color filters 530, two or more color filters 530 which are adjacent to each other may overlap. In another embodiment, among the plurality of color filters 530, two or more color filters 530 which are adjacent to each other may not overlap.

The color filter 530 may be arranged by considering the color of light emitted by the organic light-emitting diode OLED. The color filter 530 may include red, green, or blue pigments or dyes. Alternatively, the color filter 530 may further include quantum dots in addition to the pigments or dyes stated herein. Alternatively, the color filter 530 may not include the pigments or dyes stated herein, and may include scattering particles such as, for example, titanium oxide.

The planarization layer 550 may be disposed on the black matrix 510 and the color filter 530. An upper surface of the planarization layer 550 may be flat. In an embodiment, the planarization layer 550 may include an organic material. For example, the planarization layer 550 may include a polymer-based material. The polymer-based material stated herein may be transparent. For example, the planarization layer 550 may include a silicone resin, an acrylic resin, an epoxy resin, polyimide, polyethylene, or the like.

As described herein, the display panel 10 may include the first gate electrode GE1. The first gate electrode GE1 may be disposed on the first inorganic insulating layer 212, and the second inorganic insulating layer 213 may be disposed on the first gate electrode GE1. That is, the first gate electrode GE1 may be interposed between the first inorganic insulating layer 212 and the second inorganic insulating layer 213, and the first inorganic insulating layer 212 and the second inorganic insulating layer 213 may each include an inorganic insulating material. In other words, an inorganic insulating layer may be disposed over and under the first gate electrode GE1.

The first gate electrode GE1 may include a material having relatively high electrical conductivity. For example, the first gate electrode GE1 may include Mo. In an embodiment, a thickness of the first gate electrode GE1 may be 5,000 Å or more such that the first gate electrode GE1 may have sufficient electrical conductivity. As the thickness of the first gate electrode GE1 increases, residual stress of the first gate electrode GE1 may also increase.

In general, when a metal layer is formed by a method such as sputtering, the formed metal layer may have residual stress. Such residual stress is an inherent characteristic of the metal layer, which does not change even an external force is applied to the metal layer. The metal layer may have tensile stress or compressive stress as residual stress. An inorganic insulating layer formed by a method such as, for example, chemical vapor deposition (CVD) also has residual stress, and the inorganic insulating layer may have compressive stress as residual stress. Accordingly, the first gate electrode GE1, the first inorganic insulating layer 212, and the second inorganic insulating layer 213 may each have residual stress.

Because an inorganic insulating layer is more brittle than a metal layer, when external impact is applied to a display apparatus including a metal layer and an inorganic insulating layer, the inorganic insulating layer may be more vulnerable to the external impact than the metal layer. That is, the possibility in which cracks are generated in the metal layer of the display apparatus may be low, and the possibility in which cracks are generated in the inorganic insulating layer of the display apparatus may be high. Accordingly, when external impact is applied to the display apparatus 1, cracks are not generated in the first gate electrode GE1, but cracks may be generated in inorganic insulating layers disposed over and under the first gate electrode GE1. In other words, the impact resistance of the first gate electrode GE1 is high, but the impact resistance of the inorganic insulating layers disposed over and under the first gate electrode GE1 may be low.

When the metal layer and the inorganic insulating layer of the display apparatus 1 are stacked to be in contact with each other, the possibility in which cracks are generated in the inorganic insulating layer when external impact is applied to the display apparatus 1 may vary depending on the residual stress of the metal layer which is in contact with the inorganic insulating layer. For example, when external impact is applied to the display apparatus 1, the possibility in which cracks are generated in the first inorganic insulating layer 212 and the second inorganic insulating layer 213, which are disposed under or over the first gate electrode GE1, may vary depending on residual stress of the first gate electrode GE1. In other words, impact resistance of the first inorganic insulating layer 212 and the second inorganic insulating layer 213 may vary depending on the residual stress of the first gate electrode GE1.

In an embodiment, the first gate electrode GE1 may have compressive stress as residual stress. Each of the first inorganic insulating layer 212 and the second inorganic insulating layer 213 may be disposed under or over the first gate electrode GE1, and both of the first inorganic insulating layer 212 and the second inorganic insulating layer 213 may have compressive stress as residual stress. For example, each of the first inorganic insulating layer 212 and the second inorganic insulating layer 213 may have compressive stress of about 92 megapascals (MPa) as residual stress. Accordingly, as the first gate electrode GE1 has residual stress similar to that of the first inorganic insulating layer 212 and the second inorganic insulating layer 213, the impact resistance of the first inorganic insulating layer 212 and the second inorganic insulating layer 213 may be maintained such that the impact resistance is not reduced. That is, the impact resistance of the display apparatus 1 may be maintained such that the impact resistance is not reduced.

When the first gate electrode GE1 has stress opposite to that of the first inorganic insulating layer 212 and the second inorganic insulating layer 213, stress miss-match occurs, and thus the impact resistance of the first inorganic insulating layer 212 and the second inorganic insulating layer 213 may be reduced. For example, when the first gate electrode GE1 has tensile stress as residual stress, stress miss-match occurs, and thus the impact resistance of the first inorganic insulating layer 212 and the second inorganic insulating layer 213 may be reduced. That is, the impact resistance of the display apparatus 1 may be reduced.

In an embodiment, the first gate electrode GE1 may have compressive stress of 470 MPa or more and 1,540 MPa or less. In some aspects, for implementations in which the compressive stress is 470 MPa or more and 1,540 MPa or less (e.g., ranges from 470 MPa to 1,540 MPa), the impact resistance of the display apparatus 1 may be maintained such that the impact resistance is not reduced. For example, when the first gate electrode GE1 has compressive stress of less than 470 MPa, cracks generated in the first inorganic insulating layer 212 or the second inorganic insulating layer 213 due to external impact may be easily propagated within the first inorganic insulating layer 212 or the second inorganic insulating layer 213. Accordingly, lifting may occur between the first inorganic insulating layer 212 and the first gate electrode GE1 or between the second inorganic insulating layer 213 and the first gate electrode GE1. That is, the impact resistance of the display apparatus 1 may be reduced. In another example, when the first gate electrode GE1 has compressive stress of more than 1,540 MPa, the first gate electrode GE1 may be easily buckled by external impact. Accordingly, lifting may occur between the first inorganic insulating layer 212 and the first gate electrode GE1 or between the second inorganic insulating layer 213 and the first gate electrode GE1. That is, the impact resistance of the display apparatus 1 may be reduced.

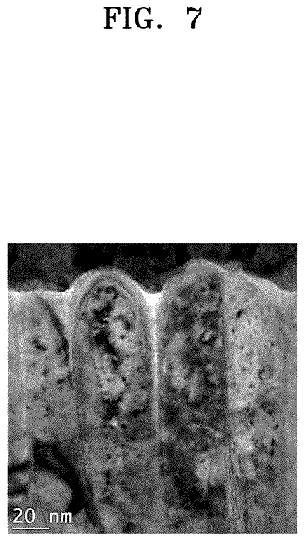

The residual stress of the first gate electrode GE1 is affected by a fine structure of the first gate electrode GE1. FIG. 7 is a photomicrograph of the first gate electrode GE1 of an embodiment of the display apparatus 1 according to the present disclosure. In particular, FIG. 7 is a transmission electron microscope photograph of capturing a longitudinal section of the first gate electrode GE1 of the display apparatus 1 according to the present disclosure in a direction parallel to the substrate 100.

As shown in FIG. 7, the first gate electrode GE1 may have a columnar structure including a plurality of columns. The plurality of columns may each have a shape extending in a direction perpendicular to the substrate 100 (e.g., z direction or −z direction). The column may have a width in the direction parallel to the substrate 100.

In an embodiment, a width of each of the plurality of columns of the first gate electrode GE1 may be 17 μm or more and 30 μm or less (e.g., range from 17 μm to 30 μm). As the width of the columns of the first gate electrode GE1 decreases, the residual stress of the first gate electrode GE1 may become more compressive. In particular, when the first gate electrode GE1 has compressive stress as residual stress, as the width of the columns of the first gate electrode GE1 decreases, the compressive stress of the first gate electrode GE1 increases. When the first gate electrode GE1 has tensile stress as residual stress, as the width of the columns of the first gate electrode GE1 decreases, the tensile stress of the first gate electrode GE1 may decrease.

In general, when a metal layer is formed by using sputtering or the like, as the size of crystal grains of the metal layer decreases, the crystal grains may be relatively densely distributed with respect to the same volume. Accordingly, the residual stress of the metal layer may become more compressive. Similarly, as the width of the columns of the first gate electrode GE1 decreases, the compressive stress of the first gate electrode GE1 increases.

When a metal layer is formed by using sputtering or the like, as the size of crystal grains of the metal layer increases, the crystal grains may be relatively loosely distributed with respect to the same volume. Accordingly, the residual stress of the metal layer may become less compressive. Similarly, as the width of the columns of the first gate electrode GE1 increases, the compressive stress of the first gate electrode GE1 decreases.

The residual stress of the metal layer may be adjusted by various factors, such as, for example, the energy of a material forming the metal layer during deposition, pressure during deposition, or a voltage applied to a substrate during deposition when forming the metal layer by using a method such as, for example, sputtering or the like. For example, as the energy of the material forming the metal layer increases during deposition, the residual stress of the metal layer may increase. A detailed description of the adjusting of the residual stress of a metal layer by using the above factors is omitted so as not to obstruct from other aspects of the present disclosure.

Descriptions given herein with respect to the material of the first gate electrode GE1, the residual stress of the first gate electrode GE1, and the fine structure of the first gate electrode GE1 may also be applied to the material of the second gate electrode GE2 and the residual stress of the second gate electrode GE2.

In particular, the second gate electrode GE2 may include a material with relatively high electrical conductivity. For example, the second gate electrode GE2 may include Mo. In an embodiment, a thickness of the second gate electrode GE2 may be 5,000 Å or more such that the second gate electrode GE2 may have sufficient electrical conductivity. In an embodiment, the second gate electrode GE2 may have compressive stress. Each of the third inorganic insulating layer 215 and the fourth inorganic insulating layer 216 may be disposed under or over the second gate electrode GE2, and both of the third inorganic insulating layer 215 and the fourth inorganic insulating layer 216 may have compressive stress as residual stress. For example, each of the third inorganic insulating layer 215 and the fourth inorganic insulating layer 216 may have compressive stress of about 92 MPa as residual stress. Accordingly, as the second gate electrode GE2 has residual stress similar to that of the third inorganic insulating layer 215 and the fourth inorganic insulating layer 216, the impact resistance of the third inorganic insulating layer 215 and the fourth inorganic insulating layer 216 may be maintained such that the impact resistance is not reduced. That is, the impact resistance of the display apparatus 1 may be maintained such that the impact resistance is not reduced.

In an embodiment, the second gate electrode GE2 may have compressive stress of 470 MPa or more and 1,540 MPa or less. In some aspects, for implementations in which the compressive stress is 470 MPa or more and 1,540 MPa or less (e.g., ranges from 470 MPa to 1,540 MPa), the impact resistance of the display apparatus 1 may be maintained such that the impact resistance is not reduced. For example, when the second gate electrode GE2 has compressive stress of less than 470 MPa, cracks generated in the third inorganic insulating layer 215 or the fourth inorganic insulating layer 216 due to external impact may be easily propagated within the third inorganic insulating layer 215 or the fourth inorganic insulating layer 216. Accordingly, lifting may occur between the third inorganic insulating layer 215 and the second gate electrode GE2 or between the fourth inorganic insulating layer 216 and the second gate electrode GE2. That is, the impact resistance of the display apparatus 1 may be reduced. In another example, when the second gate electrode GE2 has compressive stress of more than 1,540 MPa, the second gate electrode GE2 may be easily buckled by external impact. Accordingly, lifting may occur between the third inorganic insulating layer 215 and the second gate electrode GE2 or between the fourth inorganic insulating layer 216 and the second gate electrode GE2.

The second gate electrode GE2 may have a columnar structure including a plurality of columns. The plurality of columns may each have a shape extending in a direction perpendicular to the substrate 100 (e.g., z direction or −z direction). The column may have a width in the direction parallel to the substrate 100.

In an embodiment, a width of each of the plurality of columns of the second gate electrode GE2 may be 17 μm or more and 30 μm or less (e.g., range from 17 μm to 30 μm). As the width of the columns of the second gate electrode GE2 decreases, the residual stress of the second gate electrode GE2 may become more compressive. In particular, when the second gate electrode GE2 has compressive stress as residual stress, as the width of the columns of the second gate electrode GE2 decreases, the compressive stress of the second gate electrode GE2 increases. When the second gate electrode GE2 has tensile stress as residual stress, as the width of the columns of the second gate electrode GE2 decreases, the tensile stress of the second gate electrode GE2 may decrease.

### EXPERIMENTAL EXAMPLES

Hereinafter, the disclosure is described in more detail through experimental examples. However, the following experimental examples are for explaining the disclosure in more detail, and the scope of the disclosure is not limited by the following experimental examples. The following experimental examples may be appropriately modified or changed by those skilled in the art within the scope of the disclosure. The following experimental examples differ only in the residual stress and the fine structure of a gate electrode, and other conditions are the same.

TABLE 1

| | Residual | Pen drop | Width of |
|---|---|---|---|
| | stress | result | column |
| Division | (MPa) | (cm) | (μm) |
| Comparative Example 1 | 280 | 9 | 43 |
| Comparative Example 2 | 77 | 10 | 45 |
| Comparative Example 3 | 0 | 10 | 41 |
| Comparative Example 4 | −188 | 9 | 40 |
| Comparative Example 5 | −241 | 10 | 32 |
| Comparative Example 6 | −399 | 10 | 43 |
| Example 1 | −478 | 11 | 30 |
| Example 2 | −572 | 12 | 27 |
| Example 3 | −590 | 11 | 24 |
| Example 4 | −621 | 11 | 26 |
| Example 5 | −658 | 12 | 26 |
| Example 6 | −685 | 12 | 22 |
| Example 7 | −730 | 12 | 18 |
| Example 8 | −1,038 | 13 | 19 |
| Example 9 | −1,537 | 14 | 17 |
| Comparative Example 7 | −1,704 | 10 | 12 |
| Comparative Example 8 | −2,011 | 8 | 9 |

Table 1 shows impact resistance test results of the Examples and Comparative Examples of the disclosure. In particular, table 1 shows a pen drop result according to residual stress of a gate electrode of each of Examples 1 to 9 and Comparative Examples 1 to 8.

The residual stress in table 1 represents residual stress of each of gate electrodes (e.g., a first gate electrode and a second gate electrode) included in each of display apparatuses. When residual stress has a positive (+) value, it means that tensile stress is included as residual stress, and when residual stress has a negative (−) value, it means that compressive stress is included as residual stress. Expressed another way, a residual stress having a positive (+) value is a tensile stress, and residual stress having a negative (−) value is a compressive stress. Residual stress was measured by using X-ray diffraction. In particular, residual stress of each of gate electrodes was measured by comparing diffraction generated when each of the gate electrodes was irradiated with X-rays to a case where no residual stress existed.

Impact resistance was confirmed through pen drop evaluation. In particular, the pen drop evaluation was performed by vertically free-falling the same pen (e.g., a 5.8 g Fine Bic pen from the Societe Bic company) on Examples 1 to 9 and Comparative Examples 1 to 8 and measuring a height at which each of Examples 1 to 9 and Comparative Examples 1 to 8 was damaged by the pen. That is, the pen drop results of table 1 show the height at which each of Examples 1 to 9 and Comparative Examples 1 to 8 was damaged by the pen.

Referring to table 1, each of gate electrodes respectively included in Examples 1 to 9 has compressive stress of 470 MPa or more and 1,540 MPa or less (expressed another way, compressive stress ranging from 470 MPa to 1,540 MPa) as residual stress, and Examples 1 to 9 have impact resistance against a pen dropped from a height of 11 cm or more. For example, each of the first gate electrodes GE1 respectively included in Examples 1 to 9 has compressive stress of 470 MPa or more and 1,540 MPa or less as residual stress, each of the second gate electrodes GE2 respectively included in Examples 1 to 9 has compressive stress of 470 MPa or more and 1,540 MPa or less as residual stress, and Examples 1 to 9 have impact resistance against a pen dropped from a height of 11 cm or more.

In particular, each of gate electrodes of Example 1 has compressive stress of 478 MPa as residual stress, and Example 1 has impact resistance against a pen dropped from a height of 11 cm. Each of gate electrodes of Example 2 has compressive stress of 572 MPa as residual stress, and Example 2 has impact resistance against a pen dropped from a height of 12 cm. Each of gate electrodes of Example 3 has compressive stress of 590 MPa as residual stress, and Example 3 has impact resistance against a pen dropped from a height of 11 cm. Each of gate electrodes of Example 4 has compressive stress of 621 MPa as residual stress, and Example 4 has impact resistance against a pen dropped from a height of 11 cm.

Each of gate electrodes of Example 5 has compressive stress of 658 MPa as residual stress, and Example 5 has impact resistance against a pen dropped from a height of 12 cm. Each of gate electrodes of Example 6 has compressive stress of 685 MPa as residual stress, and Example 6 has impact resistance against a pen dropped from a height of 12 cm. Each of gate electrodes of Example 7 has compressive stress of 730 MPa as residual stress, and Example 7 has impact resistance against a pen dropped from a height of 12 cm. Each of gate electrodes of Example 8 has compressive stress of 1,038 MPa as residual stress, and Example 8 has impact resistance against a pen dropped from a height of 13 cm. Each of gate electrodes of Example 9 has compressive stress of 1,537 MPa as residual stress, and Example 9 has impact resistance against a pen dropped from a height of 14 cm.

Each of gate electrodes respectively included in Comparative Examples 1 to 6 has tensile stress or compressive stress of less than 470 MPa as residual stress, and Comparative Examples 1 to 6 have impact resistance against a pen dropped from a height of less than 11 cm. In particular, each of gate electrodes of Comparative Example 1 has tensile stress of 280 MPa as residual stress, and Comparative Example 1 has impact resistance against a pen dropped from a height of 9 cm. Each of gate electrodes of Comparative Example 2 has tensile stress of 77 MPa as residual stress, and Comparative Example 2 has impact resistance against a pen dropped from a height of 10 cm. Each of gate electrodes of Comparative Example 3 has compressive stress of 0 MPa as residual stress, and Comparative Example 3 has impact resistance against a pen dropped from a height of 10 cm. Each of gate electrodes of Comparative Example 4 has compressive stress of 188 MPa as residual stress, and Comparative Example 4 has impact resistance against a pen dropped from a height of 9 cm.

Each of gate electrodes of Comparative Example 5 has compressive stress of 241 MPa as residual stress, and Comparative Example 5 has impact resistance against a pen dropped from a height of 10 cm. Each of gate electrodes of Comparative Example 6 has compressive stress of 399 MPa as residual stress, and Comparative Example 6 has impact resistance against a pen dropped from a height of 10 cm. That is, in the case of Comparative Examples 1 to 6, because each of the gate electrodes has compressive stress of less than 470 MPa, cracks generated in an inorganic insulating layer (for example, a first inorganic insulating layer, a second inorganic insulating layer, a third inorganic insulating layer, or a fourth inorganic insulating layer) disposed under or over the gate electrodes due to external impact are easily propagated within the inorganic insulating layers. Accordingly, lifting occurs between the gate electrodes and inorganic insulating layers disposed under or over the gate electrodes, and thus the impact resistance of Comparative Examples 1 to 6 is reduced.

Each of gate electrodes respectively included in Comparative Examples 7 and 8 has compress stress of more than 1,540 MPa, and Comparative Examples 7 and 8 have impact resistance against a pen dropped from a height of 11 cm. In particular, each of gate electrodes of Comparative Example 7 has compressive stress of 1,704 MPa as residual stress, and Comparative Example 7 has impact resistance against a pen dropped from a height of 10 cm. Each of gate electrodes of Comparative Example 8 has compressive stress of 2,011 MPa, and Comparative Example 8 has impact resistance against a pen dropped from a height of 8 cm. That is, in the case of Comparative Examples 7 and 8, because each of the gate electrodes has compressive stress of more than 1,540, the gate electrodes are easily buckled by external impact. Accordingly, lifting occurs between the gate electrodes and inorganic insulating layers (for example, a first inorganic insulating layer, a second inorganic insulating layer, a third inorganic insulating layer, and a four inorganic insulating layer) disposed under or over the gate electrodes, and thus the impact resistance of Comparative Examples 7 and 8 is reduced.

Table 1 also shows the fine structures of Examples and Comparative Examples of the disclosure. In particular, table 1 shows a width of a column of each of gate electrodes of Examples 1 to 9 and Comparative Examples 1 to 8. The width of the column was measured by taking a photomicrograph of a cross section in a middle region of the gate electrode, that is, a region of about 50% of a thickness of the gate electrode in a direction perpendicular to a substrate. That is, the width of the column was measured by taking a photomicrograph of a cross section on a surface, which is spaced apart by ½ of the thickness of the gate electrode from one surface of the gate electrode in contact with the inorganic insulating layer to an opposite surface of the gate electrode. The width of the column of table 1 is an average value determined by measuring the widths of at least ten adjacent columns.

As described above, the residual stress of the gate electrode is affected by the fine structure of the gate electrode. When the gate electrodes have compressive stress as residual stress, as the width of the columns of the gate electrodes decreases, the compressive stress of the gate electrodes increases. Each of the columns of each of the gate electrodes of Examples 1 to 9 has a width of 17 μm or more and 30 μm or less. Accordingly, each of the gate electrodes of Examples 1 to 9 has compressive stress of 470 MPa or more and 1,540 MPa or less as residual stress.

Each of the columns of each of the gate electrodes of Comparative Examples 1 to 6 has a width of more than 30 μm. Accordingly, each of the gate electrodes of Comparative Examples 3 to 8 has compressive stress of less than 470 MPa as residual stress, and each of the gate electrodes of Comparative Examples 1 and 2 has tensile stress as residual stress. Each of the columns of each of the gate electrodes of Comparative Examples 7 and 8 has a width of less than 17 μm. Accordingly, each of the gate electrodes of Comparative Examples 7 and 8 has compressive stress of more than 1,540 MPa as residual stress.

According to an embodiment of the disclosure as described above, a display apparatus having improved impact resistance may be implemented. The scope of the disclosure is limited by these effects.

It should be understood that embodiments described herein should be considered in a descriptive sense only and not for purposes of limitation. Descriptions of features or aspects within each embodiment should typically be considered as available for other similar features or aspects in other embodiments. Descriptions of features or aspects within each embodiment should typically be considered as available for other similar features or aspects in other embodiments.

What is claimed is:

1. A display apparatus comprising:
a substrate;
a first semiconductor layer disposed on the substrate;
a first inorganic insulating layer disposed on the first semiconductor layer;
a first gate layer disposed on the first inorganic insulating layer, having a compressive stress of 470 megapascals (MPa) or more and 1,540 MPa or less, and comprising molybdenum; and
a second inorganic insulating layer disposed on the first gate layer.

2. The display apparatus of claim 1, wherein the first inorganic insulating layer has compressive stress.

3. The display apparatus of claim 2, wherein the first inorganic insulating layer comprises at least one of silicon oxide, silicon nitride, and silicon oxynitride.

4. The display apparatus of claim 1, wherein the second inorganic insulating layer has compressive stress.

5. The display apparatus of claim 4, wherein the second inorganic insulating layer comprises at least one of silicon oxide, silicon nitride, and silicon oxynitride.

6. The display apparatus of claim 1, further comprising:
a second semiconductor layer disposed over the second inorganic insulating layer;
a third inorganic insulating layer disposed on the second semiconductor layer;
a second gate layer disposed on the third inorganic insulating layer; and
a fourth inorganic insulating layer disposed on the second gate layer.

7. The display apparatus of claim 6, wherein the second gate layer has a compressive stress of 470 MPa or more and 1,540 MPa or less and comprises molybdenum.

8. The display apparatus of claim 7, wherein the third inorganic insulating layer has compressive stress, and
the third inorganic insulating layer comprises at least one of silicon oxide, silicon nitride, and silicon oxynitride.

9. The display apparatus of claim 7, wherein the fourth inorganic insulating layer has compressive stress, and
the fourth inorganic insulating layer comprises at least one of silicon oxide, silicon nitride, and silicon oxynitride.

10. The display apparatus of claim 6, wherein the first semiconductor layer comprises a silicon semiconductor, and
the second semiconductor layer comprises an oxide semiconductor.

11. A display apparatus comprising:
a substrate;
a pixel circuit layer disposed on the substrate;
a display element layer disposed on the pixel circuit layer and comprising a display element; and
an encapsulation layer disposed on the display element layer and comprising at least one inorganic encapsulation layer and at least one organic encapsulation layer,
wherein the pixel circuit layer comprises:
a first semiconductor layer disposed on the substrate;
a first inorganic insulating layer disposed on the first semiconductor layer;
a first gate layer disposed on the first inorganic insulating layer, having a compressive stress of 470 (megapascals) MPa or more and 1,540 MPa or less, and comprising molybdenum; and
a second inorganic insulating layer disposed on the first gate layer.

12. The display apparatus of claim 11, wherein the first inorganic insulating layer has compressive stress.

13. The display apparatus of claim 12, wherein the first inorganic insulating layer comprises at least one of silicon oxide, silicon nitride, and silicon oxynitride.

14. The display apparatus of claim 11, wherein the second inorganic insulating layer has compressive stress.

15. The display apparatus of claim 14, wherein the second inorganic insulating layer comprises at least one of silicon oxide, silicon nitride, and silicon oxynitride.

16. The display apparatus of claim 11, wherein the pixel circuit layer further comprises:
a second semiconductor layer disposed over the second inorganic insulating layer;
a third inorganic insulating layer disposed on the second semiconductor layer;
a second gate layer disposed on the third inorganic insulating layer; and
a fourth inorganic insulating layer disposed on the second gate layer.

17. The display apparatus of claim 16, wherein the second gate layer has a compressive stress of 470 MPa or more and 1,540 MPa or less and comprises molybdenum.

18. The display apparatus of claim 17, wherein the third inorganic insulating layer has compressive stress, and
the third inorganic insulating layer comprises at least one of silicon oxide, silicon nitride, and silicon oxynitride.

19. The display apparatus of claim 17, wherein the fourth inorganic insulating layer has compressive stress, and
the fourth inorganic insulating layer comprises at least one of silicon oxide, silicon nitride, and silicon oxynitride.

20. The display apparatus of claim 16, wherein the first semiconductor layer comprises a silicon semiconductor, and
the second semiconductor layer comprises an oxide semiconductor.
